(19) United States
(12) Patent Application Publication
(10) Pub. No.: US 2019/0097112 A1
(43) Pub. Date: Mar. 28, 2019

(54) PRODUCTION PROCESS FOR A THERMOELECTRIC DEVICE

(71) Applicant: Gentherm GmbH, Odelzhausen (DE)

(72) Inventors: Rüdiger Spillner, Augsburg (DE); Jan Horzella, Friedberg (DE)

(21) Appl. No.: 15/718,714

(22) Filed: Sep. 28, 2017

(51) Int. Cl. H01L 35/32; H01L 35/34; F25B 21/04

(52) U.S. Cl. CPC H01L 35/32; F25B 21/04; H01L 35/34

(57) ABSTRACT

The present teachings relates to a manufacturing method for a thermoelectric device having the steps: providing a first carrier layer which is made of a metal or a metal alloy in at least some sections; providing a first dielectric oxide layer on the surface of the first carrier layer, providing a first electrically conductive bridge layer on the first dielectric oxide layer and arranging a plurality of differently doped semiconductors on the first electrically conductive bridge layer such that the semiconductors are each electrically connected to the first bridge layer on the first side.

### FIELD

The present teachings relate to a thermoelectric device and a production process for a thermoelectric device, a thermoelectric generator, a thermally regulable beverage holder, a battery thermal regulating device and a climate control device for a vehicle seat.

### BACKGROUND

Thermoelectric devices are used to convert thermal energy into electrical energy or electrical energy into thermal energy. Thermoelectric devices make use of the Seebeck effect in converting thermal energy into electrical energy. Thermoelectric devices make use of the Peltier effect in converting electrical energy to thermal energy.

For implementation of these effects, thermoelectric devices usually have two opposing carrier layers spaced a distance apart from one another, wherein a plurality of p- and n-doped semiconductors is arranged between the two carrier layers. The differently doped semiconductors are connected to one another in alternation via metal bridges on opposing sides, wherein the metal bridges are attached to the carrier layers.

If a suitable temperature gradient is provided between the opposing sides of the semiconductors, a voltage potential develops. On a first side of the semiconductors, heat is then absorbed, so that electrons pass over a metal bridge to the higher energy conduction band of the following semiconductors. The electrons release thermal energy on a second opposing side of the semiconductors, so that they reach the following semiconductor via a metal bridge, said semiconductor being at a lower energy level. An electrical current flow is established in this way.

Conversely, a temperature gradient can be generated between the opposing sides of the semiconductors by providing a current flow through the semiconductors and their metal bridges.

There are two different known variants of electrical insulation of the metal bridges.

In a first approach, the carrier layers, on which the metal bridges are disposed are made of an electrically nonconductive material such as a ceramic. Although this approach ensures a reliable electrical insulation of the metal bridges, it does nevertheless result in sticking or jamming when fastening the thermal electrical device on an object. However, when sticking or jamming of a thermoelectric device impairs the heat transport and thus degrades the efficacy of the thermoelectric device.

In a second approach, the carrier layers are each coated with an insulation layer based on epoxy to electrically insulate the metal bridges. This allows the design of the carrier layers of electrically conductive metals or metal alloys so that heat transport can be achieved by welding the carrier layers of thermoelectric devices to corresponding objects to be thermally regulated. However, applying such an insulation layer results in a substantial increase in the production costs. Furthermore, the additional insulation layers necessitate an increase in the design height.

### SUMMARY

The object of the present teachings was to create the option of providing thermoelectric devices with a metallic outer surface without thereby substantially increasing the cost of manufacturing.

This object is achieved with a production process for a thermoelectric device in which a first carrier layer which is made of a metal or a metal alloy in at least some sections, a first dielectric oxide layer on the surface of the first carrier layer and a first electrically conductive bridge layer on the first dielectric oxide layer are provided and wherein several differently doped semiconductors are arranged on the first electrically conductive bridge layer in such a way that the semiconductors are each electrically connected to the first bridge layer on a first side.

The present teachings make use of the finding that an insulation layer based on epoxy can surprisingly be replaced easily by a dielectric oxide layer and in doing so in addition the electrical insulation of the electrically conductive bridge layer is ensured. Dielectric oxide layers, i.e., those that are not electrically conductive, can be created on metallic surfaces without any great manufacturing complexity and at the same time with a small layer thickness. Due to the electrical insulation by means of the dielectric oxide layer, a metallic carrier layer can thus be used and can then be welded to other objects without any great effort.

The first dielectric oxide layer is preferably provided on the entire surface or alternatively on a portion of the surface of the first carrier layer. Likewise the first electrically conductive bridge layer is preferably provided on the entire first dielectric oxide layer or alternatively on a portion of the first dielectric oxide layer.

In a preferred specific embodiment of the production process according to the present teachings, a second carrier layer which is also made of a metal or a metal alloy in at least some sections, a second dielectric oxide layer on the surface of the second carrier layer and/or a second electrically conductive bridge layer on the second dielectric oxide layer are provided. There is preferably an arrangement of the plurality of differently doped semiconductors on the second electrically conductive bridge layer such that the semiconductors are each electrically connected to the second bridge layer on a second side and all the semiconductors are electrically connected to one another by the first bridge layer and the second bridge layer.

The second dielectric oxide layer is preferably provided on the entire surface or alternatively on a portion of the surface of the second carrier layer. Likewise the second electrically conductive bridge layer is preferably provided on the entire second dielectric oxide layer or alternatively on a portion of the second dielectric oxide layer.

In an advantageous refinement of the production process according to the present teachings, the first carrier layer is made of aluminum or an aluminum alloy in at least some sections. Alternatively or additionally, providing the first dielectric oxide layer on the surface of the first carrier layer comprises anodic oxidation of the surface of the first carrier layer. The second carrier layer is also preferably made of aluminum or an aluminum alloy in at least some sections and/or providing the second dielectric oxide layer on the surface of the second carrier layer includes anodic oxidation of the surface of the second carrier layer. The anodic oxidation of the surface of the first carrier layer and/or anodic oxidation of the surface of the second carrier layer preferably includes immersion of the first carrier layer and/or the second carrier layer into an oxidation bath and providing a current flow between the first carrier layer and an electrode disposed in the oxidation bath and/or between the second carrier layer and an electrode disposed in the oxidation bath.

Alternatively the anodic oxidation of the surface of the first carrier layer and/or anodic oxidation of the surface of the second carrier layer include(s) spraying the first carrier layer and/or the second carrier layer with an electrolyte material and providing a current flow between the nozzle out of which the electrolyte material emerges and the first carrier layer and/or the second carrier layer.

In another specific embodiment of the production process according to the present teachings, providing the first dielectric oxide layer on the surface of the first carrier layer includes plasma electrolytic oxidation of the surface of the first carrier layer. Providing the second dielectric oxide layer on the surface of the second carrier layer preferably also includes plasma electrolytic oxidation of the surface of the second carrier layer. In plasma electrolytic oxidation (PEO), a metal surface is converted by means of plasma discharge to a dense atomically adhering ceramic layer. Surfaces with a hardness of up to 1200 HV and excellent adhesion properties can be produced by plasma electrolytic oxidation. Furthermore, the ceramic layer thereby produced provides corrosion protection. In addition layer thicknesses of less than 100 μm can be created by plasma electrolytic oxidation so that the design height of the thermoelectric device can be further reduced.

In another preferred specific embodiment of the production process according to the present teachings, providing the first dielectric oxide layer on the surface of the first carrier layer includes creating a eutectic melt layer on the surface of the first carrier layer, preferably by means of the direct copper bonding method. In particular providing the second dielectric oxide layer on the surface of the second carrier layer also includes creating a eutectic melt layer on the surface of the second carrier layer, preferably by means of the direct copper bonding method. The eutectic melt layer is preferably created by oxidation of one or more copper films or by supply of oxygen during a high temperature process. This eutectic melt layer reacts with the aluminum oxide and a thin copper-aluminum spinel layer is formed.

In another preferred specific embodiment of the production process according to the present teachings, the first electrically conductive bridge layer is joined to the first dielectric oxide layer, preferably using a soldering method. The joining is done in such a way that the dielectric oxide layer remains intact and retains its electrical insulation properties. The second electrically conductive bridge layer is preferably also joined to the second dielectric oxide layer, preferably by using a soldering method. Here again the joining takes place in such a way that the dielectric oxide layer remains intact and retains its electrical insulation properties.

The production process according to the present teachings is also advantageously improved by the fact that the first electrically conductive bridge layer and/or the second electrically conductive bridge layer each has/have a plurality of bridge sectors spaced a distance apart from one another. The respective bridge sectors are preferably equipped to electrically connect two differently doped semiconductors to one another. The bridge sectors thus each serve as an “electrical bridge” between the two differently doped semiconductors. In order for the bridge sectors of the first electrically conductive bridge layer and the bridge sectors of the second electrically conductive bridge layer to allow a current flow through all the semiconductors of the thermoelectric device, the arrangement and geometry of the bridge sectors of the first electrically conductive bridge layer and the arrangement and geometry of the bridge sectors of the second electrically conductive bridge layer are coordinated with one another. The production process according to the present teachings therefore preferably includes the step of producing the bridge sectors of the first electrically conductive bridge layer spaced a distance apart from one another by machining, preferably by milling the first electrically conducted bridge layer and/or the step of producing the bridge sectors of the second electrically conductive bridge layer spaced a distance apart from one another by machining, preferably milling the second electrically conductive bridge layer. The milling process allows a precise and at the same time inexpensive means of machining and is thus suitable in particular for producing individual bridge sectors spaced a distance apart from one another.

Alternatively the first electrically conductive bridge layer and/or the second electrically conductive bridge layer is/are embodied as a film, in particular as a self-stick film.

Alternatively or additionally, the production process according to the present teachings for producing the bridge sectors includes production of the bridge sectors of the first electrically conductive bridge layer spaced a distance apart from one another by etching a corresponding pattern onto the first dielectric oxide layer and/or producing the bridge sectors of the second electrically conductive bridge layer spaced a distance apart from one another by etching a corresponding pattern onto the second dielectric oxide layer. By using suitable etching templates, it is thus possible to apply corresponding patterns to the first dielectric bridge layer and/or the second dielectric bridge layer in an inexpensive and time-saving manner.

Alternatively or additionally, the production process according to the present teachings for providing the bridge sectors includes producing the bridge sectors of the first electrically conductive bridge layer spaced a distance apart from one another by printing a corresponding pattern on the first dielectric oxide layer and/or producing bridge sectors of the second electrically conductive bridge layer spaced a distance apart from one another by printing a corresponding pattern on the second dielectric oxide layer. When printing the corresponding pattern, it is preferable to use a 3D printer which applies the pattern in the desired thickness in one or more material layers to the first dielectric oxide layer and/or the second dielectric oxide layer. By using a printing method it is possible to implement complex bridge geometries without high manufacturing effort and costs.

In another advantageous refinement, the production process according to the present teachings includes producing the bridge sectors of the first electrically conductive bridge layer spaced a distance apart from one another by creating a corresponding pattern on the first dielectric oxide layer by means of physical gas phase deposition and/or producing the bridge sectors of the second electrically conductive bridge layer spaced a distance apart from one another by creating a corresponding pattern on the second dielectric oxide layer by means of physical gas phase deposition. Production of the bridge sectors of the first electrically conductive bridge layer spaced a distance apart from one another and/or the second electrically conductive bridge layer by means of physical gas phase deposition preferably takes place by means of a vaporization process, such as thermal evaporation, electron beam evaporation, laser beam evaporation, electrical arc evaporation or molecular beam epitaxy. Alternatively or additionally, the production of the bridge sectors of the first electrically conductive bridge layer spaced a distance apart from one another and/or of the second electrically conductive bridge layer takes place by means of physical gas phase deposition with sputtering as in the MAD method (ion beam assisted deposition), by means of ionic plating or by the ICBD method (ionized cluster beam deposition).

Alternatively or additionally, the production process according to the present teachings for providing the bridge sectors includes production of the bridge sectors of the first electrically conductive bridge layer spaced a distance apart from one another by creating a corresponding pattern on the first dielectric oxide layer by means of chemical gas phase deposition and/or producing the bridge sectors of the second electrically conductive bridge layer spaced a distance apart from one another by creating a corresponding pattern on the second dielectric oxide layer by means of chemical gas phase deposition. Production of the bridge sectors of the first electrically conductive bridge layer spaced a distance apart from one another and/or the second electrically conductive bridge layer by means of chemical gas phase deposition preferably takes place by means of plasma-assisted chemical gas phase deposition, chemical gas phase deposition at low pressure, chemical gas phase deposition at atmospheric pressure, organometallic chemical gas phase deposition or chemical gas phase infiltration.

In a particularly preferred specific embodiment of the production process according to the present teachings, the first electrically conductive bridge layer is made of copper or a copper alloy. Alternatively or additionally the second electrically conductive bridge layer is made of copper or a copper alloy. Copper or copper alloys are particularly suitable for being joined to the first carrier layer made of aluminum or an aluminum alloy and/or the second carrier layer without any damage to the first dielectric oxide layer or the first carrier layer and/or the second dielectric oxide layer on the second carrier layer. Therefore, using copper or a copper alloy reduces the risk of impairment or even elimination of the insulation properties of the first dielectric oxide layer and/or the insulation properties of the second dielectric oxide layer properties during the joining of the first carrier layer to the first electrically conductive bridge layer and/or during the joining of the second carrier layer to the second electrically conductive bridge layer. Joining the first carrier layer to the first electrically conductive bridge layer and/or joining the second carrier layer to the second electrically conductive bridge layer take(s) place preferably by means of active soldering, in particular by using solder with a titanium content. The joining of the first carrier layer to the first electrically conductive bridge layer and/or the joining of the second carrier layer to the second electrically conductive bridge layer may also take place by means of soft soldering, in particular using soft solder based on tin/lead.

The production process according to the present teachings is also advantageously improved by galvanizing the first electrically conductive bridge layer, preferably for creating a nickel coating or a copper coating and/or by galvanizing the second electrically conductive bridge layer, preferably for creating a nickel coating or a copper coating. Galvanization increases the corrosion resistance and wear resistance. Furthermore, with certain pairings of materials, the electrical conductivity can be improved by creating a nickel coating or a copper coating so that the efficacy of the thermoelectric device is enhanced.

In another advantageous embodiment of the production process according to the present teachings, the joining of the plurality of the differently doped semiconductors to the first electrically conductive bridge layer takes place preferably by using a soldering process and/or the joining of the plurality of differently doped semiconductors to the second electrically conductive bridge layer preferably takes place by using a soldering process. Due to the joining of the plurality of differently doped semiconductors to the first electrically conductive bridge layer and/or the joining of the plurality of differently doped semiconductors to the second electrically conductive bridge layer, on the one hand, the heat transport between the semiconductors and the respective electrically conductive bridge layer is increased and, on the other hand, the electrical conductivity of the corresponding connection is increased. Soldering processes are especially suitable for joining the plurality of differently doped semiconductors to the first electrically conductive bridge layer and/or the second electrically conductive bridge layer. Soldering processes produce a robust and inexpensive physically bonded joint so that the advantages referred to can be achieved without a substantial increase in the production effort/cost. The soldering of the plurality of differently doped semiconductors to the first electrically conductive bridge layer and/or the second electrically conductive bridge layer preferably take(s) place under compressive stress so that the quality of the connection can be further increased.

The object of the present teachings is also achieved by a thermoelectric device with a first carrier layer, a first dielectric oxide layer, a first electrically conductive bridge layer and a plurality of differently doped semiconductors. The first carrier layer is made of metal or a metal alloy in at least some sections. The first dielectric oxide layer is arranged on the surface of the first carrier layer and the first electrically conductive bridge layer is arranged on the first dielectric oxide layer. The plurality of differently doped semiconductors is disposed on the first electrically conductive bridge layer in such a way that the semiconductors are each electrically connected to the first bridge layer on the first side. The thermoelectric device according to the present teachings may be used as a Peltier element for cooling or heating by means of electrical energy or as a Seebeck element to convert heat into electrical energy. Furthermore, the thermoelectric device according to the present teachings has a metallic outer surface without causing a substantial increase in production costs because it is possible then to omit an additional protective layer based on epoxy due to the dielectric oxide layer.

An advantageous specific embodiment of the thermoelectric device according to the present teachings comprises a second carrier layer, a second dielectric oxide layer and a second electrically conductive bridge layer. The second carrier layer is made of metal or a metal alloy in at least some sections. The second dielectric oxide layer is disposed on the surface of the second carrier layer and the second electrically conductive bridge layer is disposed on the second dielectric oxide layer. The plurality of differently doped semiconductors is arranged on the second electrically conductive bridge layer in such a way that the semiconductors are each electrically connected to the second bridge layer on a second side, and all the semiconductors are connected to one another by the first bridge layer and the second bridge layer.

In a preferred specific embodiment of the thermoelectric device according to the present teachings, the first carrier layer and/or the second carrier layer is made of aluminum or an aluminum alloy in at least some sections. Aluminum has excellent thermal conduction properties and can be physically bonded to other metals or metal alloys by various joining methods, for example, welding, without resulting in a substantial impairment of the heat transport due to the joint connection.

The thermoelectric device according to the present teachings is further improved upon by the fact that the first electrically conductive bridge layer is soldered to the first dielectric oxide layer, and/or the second electrically conductive bridge layer is soldered to the second dielectric oxide layer. The respective electrically conductive bridge layer is soldered to the corresponding dielectric oxide layer, such that the corresponding dielectric oxide layer is not damaged by the soldering operation and retains its electrical insulation properties.

In a refinement of the thermoelectric device according to the present teachings, the first electrically conductive bridge layer and/or the second electrically conductive bridge layer each has/have a plurality of bridge sectors spaced a distance apart from one another. The respective bridge sectors are preferably equipped for each to electrically connect two differently doped semiconductor to one another. The bridge sectors thus each serve as an “electrical bridge” between two differently doped semiconductors. In order for the bridge sectors of the first electrically conductive bridge layer and the bridge sectors of the second electrically conductive bridge layer to allow a current flow through all the semiconductors of the thermoelectric device, the arrangement and the geometry of the bridge sectors of the first electrically conductive bridge layer and the arrangement and geometry of the bridge sectors of the second electrically conductive bridge layer are coordinated with one another.

In a particularly preferred specific embodiment of the thermoelectric device according to the present teachings, the first electrically conductive bridge layer and/or the second electrically conductive bridge layer is/are made of copper or a copper alloy. Copper or copper alloys are particularly suitable for being joined to the first carrier layer and/or second carrier layer made of aluminum or an aluminum alloy without any damage to the first dielectric oxide layer on the first carrier layer and/or to the second dielectric oxide layer on the second carrier layer. The thermoelectric device according to the present teachings thus has a substantially reduced risk of a malfunction because there is no damage to the insulating oxide layer during production.

If an alternative specific embodiment of the thermoelectric device according to the present teachings, the first electrically conductive bridge layer and/or the second electrically conductive bridge layer has/have a nickel coating or a copper coating. The nickel coating or the copper coating serves as corrosion protection and wear protection and increases the electrical conductivity for certain pairs of material so that the long life and efficacy of the thermoelectric device are increased.

Furthermore, a thermoelectric device according to the present teachings in which the plurality of differently doped semiconductors is soldered to the first electrically conductive bridge layer and/or to the second electrically conductive bridge layer is preferred. Due to the soldered connections, the heat transport between the semiconductors and the respective electrically conductive bridge layer is increased, and the electrically conductivity of the corresponding connection is increased. The soldered connection is a robust, physically bonded connection, which is inexpensive to produce and for this reason is especially suitable for joining the different doped semiconductors to the first electrically conductive bridge layer and/or to the second electrically conductive bridge layer.

In a particularly preferred specific embodiment, the thermoelectric device is designed to be nondestructively shapeable, in particular bendable. The thermoelectric device is preferably is nondestructively rotatable about a plurality of axes and/or nondestructively bendable in multiple directions. This is achieved in particular by the fact that individual or all components and/or individual or all joints of the thermoelectric device can be shaped nondestructively and/or are arranged at a distance from one another such that deformation of the thermoelectric device is possible without any deformation of individual components, for example, the plurality of differently doped semiconductors. The first carrier layer, the second carrier layer, the first dielectric oxide layer, the second dielectric oxide layer, the first electrically conductive bridge layer and/or the second electrically conductive bridge layer are preferably designed as nondestructively deformable material layers. The nondestructive deformability allows adaptation of the thermoelectric device to the geometry of other objects, for example, to the geometry of a beverage holder or a vehicle seat. In a beverage holder or in a vehicle seat, the thermoelectric device may be used as a thermally regulating device for heating or cooling. Furthermore, the nondestructive deformability allows the thermoelectric device to be mounted on various design shapes of electrical components, such as rechargeable batteries or heat-carrying fluid channels inside a motor vehicle, such as the exhaust system.

In an advantageous refinement of the thermoelectric device according to the present teachings, the latter is produced by means of a manufacturing process for a thermoelectric device according to any one of the specific embodiments described above. With regard to the advantages of such a thermoelectric device according to the present teachings, reference is made to the advantages of the manufacturing process according to the present teachings.

The object on which the present teachings is based is also achieved by a thermoelectric generator, wherein the thermoelectric generator according to the present teachings has one or more thermoelectric devices according to any one of the specific embodiments described above. With respect to the advantages of the thermoelectric generator according to the present teachings, reference is made to the advantages of the thermoelectric device according to the present teachings.

The object on which the present teachings is based is also achieved by a thermally regulable beverage holder, wherein the thermally regulable beverage holder according to the present teachings has a receptacle device and one or more thermoelectric devices designed as Peltier elements. The receptacle device is equipped to accommodate a beverage container and provides a thermally regulable space for the beverage container. The one or more thermoelectric devices designed as Peltier elements are coupled to the thermally regulable space in such a way as to transmit heat and are designed according to any one of the specific embodiments described above. With regard to the advantages of the thermally regulable beverage holder according to the present teachings, reference is made to the advantages of the thermoelectric device according to the present teachings.

The object on which the present teachings is based is also achieved by a battery thermal regulating device, wherein the battery thermal regulating device according to the present teachings comprises one or more thermoelectric devices designed as Peltier elements, according to any one of the specific embodiments described above. With regard to the advantages of the battery thermal regulating device according to the present teachings, reference is made to the advantages of the thermoelectric device according to the present teachings.

A preferred specific embodiment of the battery thermal regulating device according to the present teachings comprises one or more storage units for electrical energy, wherein the one or more thermal electrical devices are coupled to the one or more storage devices so as to transmit heat. The one or more thermoelectric devices are preferably mounted on the one or more storage units, in particular by means of a welded joint, a soldered joint, an adhesive connection, a screw connection or a clamped connection.

The object on which the present teachings is based is also achieved by a climate control device for a vehicle seat, wherein the climate control device according to the present teachings comprises one or more thermoelectric devices designed as Peltier elements which are designed according to any one of the specific embodiments described above. With regard to the advantages of the climate control device according to the present teachings, reference is made to the advantages of the thermoelectric device according to the present teachings.

The present teachings provide: a thermoelectric device of the teachings herein wherein the thermoelectric device may be manufactured by a manufacturing method for a thermoelectric device according to the teachings herein.

The present teachings provide: a climate control device for a vehicle seat having one or more thermoelectric devices designed as Peltier elements, wherein the one or more thermoelectric devices may be designed according to the teachings herein.

### BRIEF DESCRIPTION OF THE DRAWINGS

Preferred specific embodiments of the present teachings are explained in greater detail and described below with reference to the accompanying drawings, in which:

FIG. 1 shows an exemplary embodiment of the thermoelectric device according to the present teachings in a side view;

FIG. 2a shows a first carrier layer of a thermoelectric device according to the present teachings;

FIG. 2b shows a second carrier layer of a thermoelectric device according to the present teachings;

FIG. 2c shows a plurality of different doped semiconductors of a thermoelectric device according to the present teachings;

FIG. 3 shows a motor vehicle with a thermoelectric generator according to the present teachings;

FIG. 4 shows an exemplary embodiment of the thermally regulable beverage holder according to the present teachings;

FIG. 5 shows a vehicle seat with a climate control device according to the present teachings; and

FIG. 6 shows an exemplary embodiment of the method according to the present teachings as a block diagram.

### DETAILED DESCRIPTION

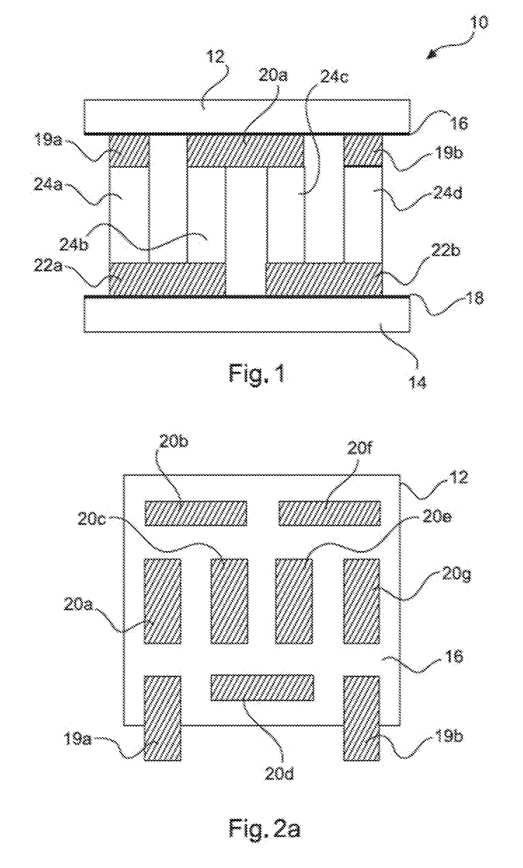

FIG. 1 shows a thermoelectric device 10 according to the present teachings with a first carrier layer 12 and a second carrier layer 14, wherein the first carrier layer 12 and the second carrier layer 14 are each completely made of aluminum.

A first dielectric oxide layer 16 is arranged on the surface of the first carrier layer 12, which faces the second carrier layer 14. A second dielectric oxide layer 18 is arranged on the surface of the second carrier layer 14, which faces the first carrier layer 12.

A first electrically conductive bridge layer 19a, 19b, 20a which has two terminals 19a, 19b and one bridge sector 20a is arranged on the first dielectric oxide layer 16. A second electrically conductive bridge layer 22a, 22b, which has two bridge sectors 22a, 22b a distance apart from one another, is arranged on the second dielectric oxide layer 18.

A total of four different doped semiconductors 24a-24d are arranged on the first electrically conductive bridge layer 19a, 19b, 20a, such that the semiconductors 24a-24d are each connected electrically on the first side to one of the terminals 19a, 19b or the bridge sector 20a of the first bridge layer 19a, 19b, 20a. The four different doped semiconductors 24a-24d are also arranged on the second electrically conductive bridge layer 22a, 22b in such a way that the semiconductors 24a-24d are each connected electrically on the second side to a bridge sector 22a, 22b of the second bridge layer 22a, 22b.

The terminals 19a, 19b and the bridge sector 20a of the first electrically conductive bridge layer 19a, 19b, 20a are made of copper, have a nickel coating and are soldered to the first dielectric oxide layer 16. The bridge sectors 22a, 22b of the second electrically conductive bridge layer 22a, 22b are made of copper, have a nickel coating and are soldered to the second dielectric oxide layer 18.

The semiconductors 24a, 24c are designed as n-doped semiconductors. The semiconductors 24b, 24d are designed as p-doped semiconductors. The semiconductor 24a is soldered to the terminal 19a and the bridge sector 22a. The semiconductor 24b is soldered to the bridge sector 22a and the bridge sector 20a. The semiconductor 24c is soldered to the bridge sector 20a and the bridge sector 22b. The semiconductor 24d is soldered to the bridge sector 22b and the terminal 19b.

The thermoelectric device 10 illustrated here is produced by a manufacturing method for a thermoelectric device 10 according to any one of claims 1 to 9.

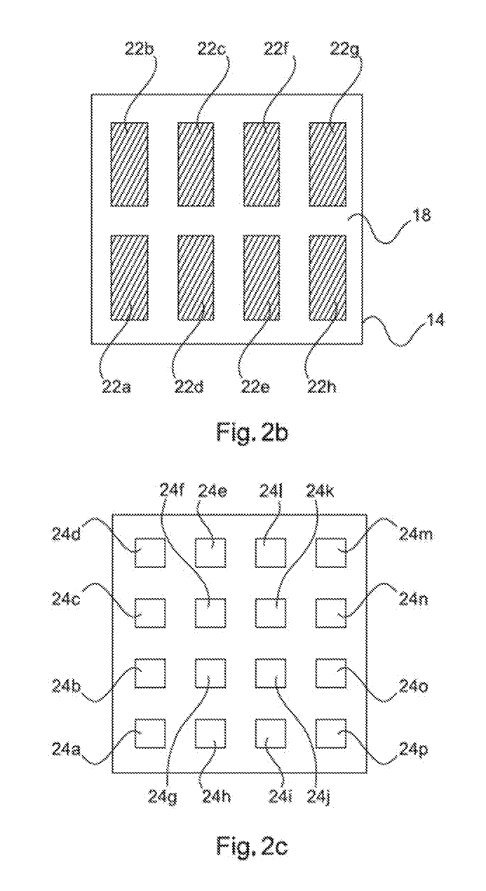

FIG. 2a shows a first carrier layer 12 of a thermoelectric device according to the present teachings. The first carrier layer 12 is made completely of an aluminum alloy. A first dielectric oxide layer 16 is arranged on the surface of the first carrier layer 12. A first electrically conductive bridge layer 19a, 19b, 20a-20g which has two terminals 19a, 19b and seven bridge sectors 20a-20g is arranged on the first dielectric oxide layer 16. The terminals 19a, 19b and the bridge sectors 20a-20g of the first electrically conductive bridge layer 19a, 19b, 20a are made of copper, have a nickel coating and are soldered to the first dielectric oxide layer 16.

FIG. 2b shows a second carrier layer 14 of a thermoelectric device according to the present teachings. The second carrier layer 14 is made completely of an aluminum alloy. A second dielectric oxide layer 18 is arranged on the surface of the second carrier layer 14. A second electrically conductive bridge layer 22a-22h which has eight bridge sectors 22a-22h is arranged on the second dielectric oxide layer 18. The bridge sectors 22a-22h of the second electrically conductive bridge layer 22a-22h are made of copper, have a nickel coating and are soldered to the second dielectric oxide layer 18.

FIG. 2c shows a total of 16 differently doped semiconductors 24a-24p. The differently doped semiconductors 24a-24p are each adapted for being connected on the first side to one of the terminals 19a, 19b or to one of the seven bridge sectors 20a-20g from FIG. 2a and on a second side to one of the bridge sectors 22a-22h from FIG. 2b.

The semiconductors 24a, 24c, 24e, 24g, 24i, 24k, 24m, 24o are designed as n-doped semiconductors. The semiconductors 24b, 24d, 24f, 24h, 24j, 24l, 24n, 24p are designed as p-doped semiconductors. The following soldering pattern is obtained after joining the semiconductors 24a-24p shown in FIG. 2c to the modules illustrated in FIGS. 2a and 2b: The semiconductor 24a is soldered to the terminal 19a and to the bridge sector 22a. The semiconductor 24b is soldered to the bridge sector 22a and to the bridge sector 20a. The semiconductor 24c is soldered to the bridge sector 20a and to the bridge sector 22b. The semiconductor 24d is soldered to the bridge sector 22b and to the bridge sector 20b. The semiconductor 24e is soldered to the bridge sector 20b and to the bridge sector 22c. The semiconductor 24f is soldered to the bridge sector 22c and to the bridge sector 20c. The semiconductor 24g is soldered to the bridge sector 20c and to the bridge sector 22d. The semiconductor 24h is soldered to the bridge sector 22d and to the bridge sector 20d. The semiconductor 24i is soldered to the bridge sector 20d and to the bridge sector 22e. The semiconductor 24j is soldered to the bridge sector 22e and to the bridge sector 20e. The semiconductor 24k is soldered to the bridge sector 20e and to the bridge sector 22f. The semiconductor 24l is soldered to the bridge sector 22f and to the bridge sector 20f. The semiconductor 24m is soldered to the bridge sector 20f and to the bridge sector 22g. The semiconductor 24n is soldered to the bridge sector 22g and to the bridge sector 20g. The semiconductor 24o is soldered to the bridge sector 20g and to the bridge sector 22h. The semiconductor 24p is soldered to the bridge sector 22h and to the terminal 19b.

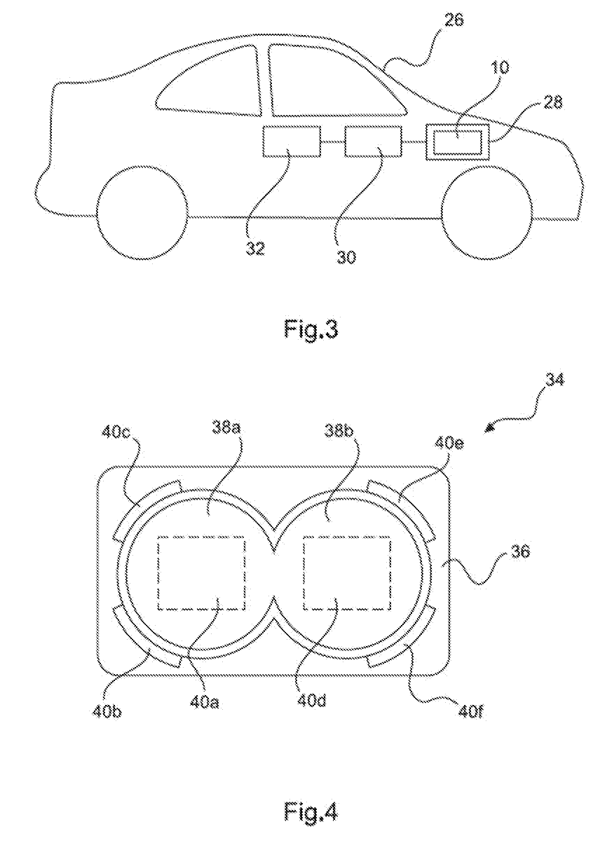

FIG. 3 shows a vehicle 26 with a thermoelectric generator 28 according to the present teachings. The thermoelectric generator 28 comprises a thermoelectric device 10 according to any of the teachings herein. The thermoelectric device 10 is connected to the exhaust gas line of the motor vehicle 26, so that it can conduct heat and convert the heat emitted there into electrical energy by utilizing the Seebeck effect. The electrical energy generated in this way is stored by means of a storage device 30 for electrical energy, for example, a lithium ion-based rechargeable battery. The storage device 30 for electrical energy makes available the stored electrical energy to a consumer 32 in the motor vehicle 26.

FIG. 4 shows a thermally regulable beverage holder 34 according to the present teachings. The thermally regulable beverage holder 34 comprises a receptacle device 36, which is equipped for accommodating two beverage containers and each supplies a thermally regulable space 38a, 38b for a beverage container. The beverage containers may be cups or cans, for example.

In the area of the thermally regulable spaces 38a, 38b of the receptacle device 36, a thermoelectric device is welded to the bottom as a Peltier element 40a, 40d. Two additional thermoelectric devices 40b, 40c designed as Peltier elements are disposed on the outer edge of the thermally regulable space 38a radially. Furthermore, two thermoelectric devices designed as Peltier elements 40e, 40f are arranged on the outer edge of the thermally regulable space 38b radially.

The thermoelectric devices designed as Peltier elements 40b, 40c, 40e, 40f are nondestructively deformable, namely nondestructively bendable.

The thermoelectric devices designed as Peltier elements 40a-40c are coupled to the thermally regulable space 38a in such a way as to transmit heat. The thermoelectric devices designed as Peltier elements 40d-40f are coupled to the thermally regulable 38a so as to transmit heat. All the Peltier elements 40a-40f are designed according to any of the teachings herein.

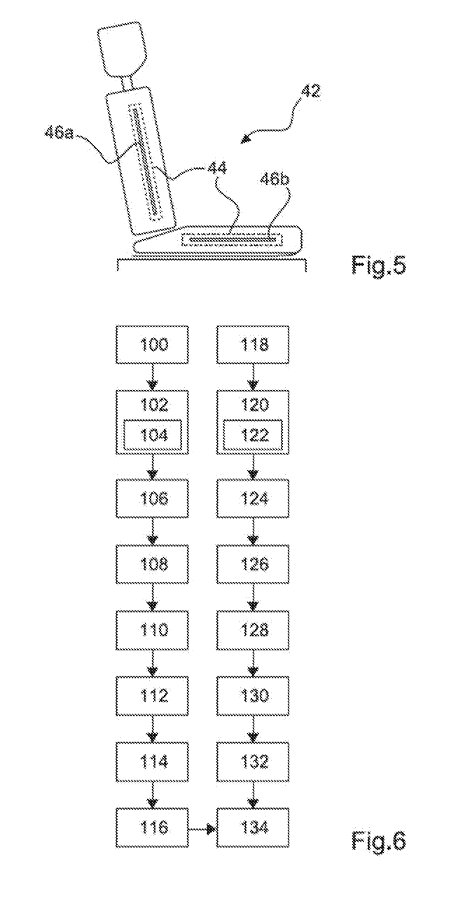

FIG. 5 shows a vehicle seat 42 with a climate control device 44 according to the present teachings. The climate control device 44 according to the present teachings comprises two thermoelectric devices designed as Peltier elements 46a, 46b. The thermoelectric device designed as a Peltier element 46a is integrated into the backrest of the vehicle seat 42. The thermoelectric device designed as a Peltier element 46b is integrated into the seat cushion of the vehicle seat 42. The two thermoelectric devices, in the form of Peltier elements 46a, 46b, are designed according to any of the teachings herein.

FIG. 6 shows the production process according to the present teachings for a thermoelectric device. The production process begins with the steps:

100) Providing a first carrier layer which is made completely of aluminum, and

102) Providing a first dielectric oxide layer on the surface of the first carrier layer.

The first dielectric oxide layer is provided on the surface of the first carrier layer by means of the following step:

104) Anodic oxidation of the surface of the first carrier layer.

After creating the first dielectric oxide layer, electrically conductive metal bridges are provided on the first carrier layer and joined to it by means of the following step:

106) Galvanizing a first electrically conductive bridge layer for creating a nickel coating;

108) Providing the coated first electrically conductive bridge layer on the first dielectric oxide layer and

110) Joining the first electrically conductive coated bridge layer to the first dielectric oxide layer using a soldering process.

After soldering the coated first electrically conductive bridge layer to the first dielectric oxide layer, the following steps are carried out:

112) Producing bridge sectors of the first electrically conductive bridge layer spaced a distance apart from one another by milling the first electrically conductive bridge layer;

114) Arranging a plurality of p-doped and n-doped semiconductors on the bridge sectors of the first electrically conductive bridge layers spaced a distance apart from one another such that the semiconductors are each electrically connected to the bridge sectors of the first bridge layer spaced a distance apart from one another and

116) Joining the plurality of p-doped and n-doped semiconductors to the bridge sectors of the first electrically conductive bridge layer spaced a distance apart from one another by using a soldering process.

Simultaneously with the steps 100 to 116 or after carrying out the steps 100 to 116, the following steps are carried out:

118) Providing a second carrier layer which is made completely of aluminum;

120) Providing a second dielectric oxide layer on the surface of the second carrier layer.

Providing the second dielectric oxide layer on the surface of the second carrier layer comprises the following step:

122) Anodic oxidation of the surface of the second carrier layer.

After creating the second dielectric oxide layer, electrically conductive metal bridges are provided on the second carrier layer in the following steps and are joined thereto:

124) Galvanizing a second electrically conductive bridge layer for creating a nickel coating;

126) Providing the coated second electrically conductive bridge layer on the second dielectric oxide layer and

128) Joining the coated second electrically conductive bridge layer with the second dielectric oxide layer by using a soldering process.

After soldering the coated second electrically conductive bridge layer to the second dielectric dioxide layer the following steps are carried out:

130) Producing the bridge sectors of the second electrically conductive bridge layer spaced a distance apart from one another by milling the second electrically conductive bridge layer;

132) Arranging the plurality of p-doped and n-doped semiconductors on the bridge sector of the second electrically conductive bridge layer spaced a distance apart from one another such that the semiconductors are each electrically connected on the second side to the bridge sectors of the second bridge layer spaced a distance apart from one another and all semiconductors are electrically connected to one another by the first bridge layer and the second bridge layer; and

134) Joining the plurality of p-doped and n-doped semiconductors to the bridge sectors of the second electrically conductive bridge layer spaced a distance apart from one another by using a soldering process.

### LIST OF REFERENCE NUMERALS

10 Thermoelectric device
12 First carrier layer
14 Second carrier layer
16 First dielectric oxide layer
18 Second dielectric oxide layer
19a, 19b Terminals
20a-20g Bridge sectors
22a-22h Bridge sectors
24a-24p Semiconductor
26 Motor vehicle
28 Thermoelectric generator
30 Storage device
32 Consumer
34 Thermally regulable beverage holder
36 Receptacle device
38a, 38b Thermally regulable space
40a-40f Peltier elements
42 Vehicle seat
44 Climate control device
46a, 46b Peltier elements
100-134 Method steps

1. A manufacturing method for a thermoelectric device, having the steps:
providing a first carrier layer which is made of a metal or metal alloy in at least some sections;
providing a first dielectric oxide layer on a surface of the first carrier layer;
providing a first electrically conductive bridge layer on the first dielectric oxide layer; and
arranging a plurality of differently doped semiconductors on the first electrically conductive bridge layer so that the semiconductors are each electrically connected to the first electrically conductive bridge layer on a first side.

2. The manufacturing method according to claim 1, also comprising one, more or all the following step:
providing a second carrier layer which is made of a metal or a metal alloy in at least some sections;
providing a second dielectric oxide layer on a surface of the second carrier layer;
providing a second electrically conductive bridge layer on the second dielectric oxide layer;
arranging the plurality of differently doped semiconductors on the second electrically conductive bridge layer in such a way that the semiconductors are each electrically connected to the second-bridge layer on a second side, and all the semiconductors are electrically connected to one another by the first bridge layer and the second bridge layer.

3. The manufacturing method according to claim 1, wherein the first carrier layer is made of aluminum or an aluminum alloy in at least some sections, and providing the first dielectric oxide layer on the surface of the first carrier layer comprises the following step:
anodic oxidation of the surface of the first carrier layer; and/or
wherein the second carrier layer is made of aluminum or an aluminum alloy in at least some sections, and providing the second dielectric oxide layer on the surface of the second carrier layer comprises the following step:
anodic oxidation of the surface of the second carrier layer.

4. The manufacturing method according to claim 1, comprising at least one of the following steps:
joining the first electrically conductive bridge layer to the first dielectric oxide layer;
joining the second electrically conductive bridge layer to the second dielectric oxide layer.

5. The manufacturing method according to claim 1, wherein the first electrically conductive bridge layer and/or the second electrically conductive bridge layer each has/have a plurality of bridge sectors spaced a distance apart from one another, and the manufacturing method comprises one, more or all of the following steps:
manufacturing the bridge sectors of the first electrically conductive bridge layer spaced a distance apart from one another by machining or by milling the first electrically conductive bridge layer;
manufacturing the bridge sectors of the second electrically conductive bridge layer spaced a distance apart from one another by machining or by milling the second electrically conductive bridge layer;
manufacturing the bridge sectors of the first electrically conductive bridge layer spaced a distance apart from one another by etching a corresponding pattern onto the first dielectric oxide layer;
manufacturing the bridge sectors of the second electrically conductive bridge layer spaced a distance apart from one another by etching a corresponding pattern onto the second dielectric oxide layer;
manufacturing the bridge sectors of the first electrically conductive bridge layer spaced a distance apart from one another by printing a corresponding pattern onto the first dielectric oxide layer;
manufacturing the bridge sectors of the second electrically conductive bridge layer spaced a distance apart from one another by printing a corresponding pattern onto the second dielectric oxide layer.

6. The manufacturing method according to claim 1, wherein the first electrically conductive bridge layer and/or the second electrically conductive bridge layer each has/have a plurality of bridge sectors spaced a distance apart from one another, and the manufacturing method comprises one, more or all of the following steps:
manufacturing the bridge sectors of the first electrically conductive bridge layer spaced a distance apart from one another by creating a corresponding pattern on the first dielectric oxide layer by means of physical gas phase deposition;
manufacturing the bridge sectors of the second electrically conductive bridge layer spaced a distance apart from one another by creating a corresponding pattern on the second dielectric oxide layer by means of physical gas phase deposition;
manufacturing the bridge sectors of the first electrically conductive bridge layer spaced a distance apart from one another by creating a corresponding pattern on the first dielectric oxide layer by means of chemical gas phase deposition;
manufacturing the bridge sectors of the second electrically conductive bridge layer spaced a distance apart from one another by creating a corresponding pattern on the second dielectric oxide layer by means of chemical gas phase deposition.

7. The manufacturing method according to claim 1, wherein the first electrically conductive bridge layer and/or the second electrically conductive bridge layer is/are made of copper or a copper alloy.

8. The manufacturing method according to claim 1, comprising at least one of the following steps:
galvanizing the first electrically conductive bridge layer for producing a nickel coating or a copper coating;
galvanizing the second electrically conductive bridge layer for creating a nickel coating or a copper coating.

9. The manufacturing method according to claim 1, comprising at least one of the following steps:
joining the plurality of differently doped semiconductors to the first electrically conductive bridge layer using a soldering process;
joining the plurality of differently doped semiconductors to the second electrically conductive bridge layer using a soldering process.

10. A thermoelectric device comprising:
a first carrier layer which is made of metal or a metal alloy in at least some sections;
a first dielectric oxide layer on a surface of the first carrier layer;
a first electrically conductive bridge layer on a first dielectric oxide layer; and
a plurality of differently doped semiconductors on the first electrically conductive bridge layer,
wherein the semiconductors are arranged in such a way that the semiconductors are each electrically connected to the first electrically conductive bridge layer on a first side.

11. The thermoelectric device according to claim 10, comprising:
a second carrier layer which is made of metal or a metal alloy in at least some sections;
a second dielectric oxide layer on a surface of the second carrier layer and
a second electrically conductive bridge layer on the second dielectric oxide layer;
wherein the semiconductors are arranged on the second electrically conductive bridge layer in such a way that the semiconductors are each electrically connected to a second bridge layer on a second side and all the semiconductors are electrically connected to one another by the first bridge layer and the second bridge layer.

12. The thermoelectric device according to claim 10, wherein the first carrier layer and/or the second layer is/are made of aluminum or an aluminum alloy in at least some sections.

13. The thermoelectric device according to claim 10, wherein the first electrically conductive bridge layer is soldered to the first dielectric oxide layer and/or wherein the second electrically conductive bridge layer is soldered to the second dielectric oxide layer.

14. The thermoelectric device according to claim 10, wherein the first electrically conductive bridge layer and/or the second electrically conductive bridge layer each has/have a plurality of bridge sectors spaced a distance apart from one another.

15. The thermoelectric device according to claim 10, wherein the first electrically conductive bridge layer and/or the second electrically conductive bridge layer is made of copper or a copper alloy or has/have a nickel coating or a copper coating.

16. The thermoelectric device according to claim 10, wherein the plurality of differently doped semiconductors are soldered to the first electrically conductive bridge layer and/or to the second electrically conductive bridge layer.

17. The thermoelectric device according to claim 10, wherein the thermoelectric device is designed to be nondestructively deformable or bendable.

18. The thermoelectric generator comprising:
one or more thermoelectric devices according to claim 10.

19. A thermally regulable beverage holder comprising:
a receptacle device which is equipped to accommodate a beverage container and provides a thermally regulable space for the beverage container; and
one or more thermoelectric devices designed as Peltier elements, wherein the one or more thermoelectric devices is/are coupled to the thermally regulable space in a heat-transmitting manner and are designed according to claim 10.

20. A battery thermally regulable device comprising:
one or more thermoelectric devices designed as Peltier elements, wherein the one or more thermoelectric devices is/are designed according to claim 10.
